(19) United States
(12) Patent Application Publication
(10) Pub. No.: US 2024/0361369 A1
(43) Pub. Date: Oct. 31, 2024

(54) REMOTELY CONTROLLED ROTORCRAFT FOR MEASURING BY ESTABLISHING CONTACT POINTS

(71) Applicant: SUPAIRVISION, Rosieres-Pres-Troyes (FR)

(72) Inventors: David PERINET, Troyes (FR); Zhewei YU, Reims (FR); Sebastien ARNOULD, Le Fresne (FR)

(21) Appl. No.: 18/579,289

(22) PCT Filed: Jul. 18, 2022
(86) PCT No.: PCT/IB22/56593

§ 371 Date: Jan. 12, 2024

(30) Foreign Application Priority Data
Jul. 16, 2021 (FR) FR2107705

(51) Int. Cl. G01R 27/02; B64U 10/14; B64U 10/60; B64U 101/26; B64U 101/30; F03D 17/00

(52) U.S. Cl. CPC G01R 27/02; B64U 10/14; B64U 10/60; B64U 2101/26; B64U 2101/30; B64U 2201/202; F03D 17/003; F03D 17/004

(57) ABSTRACT

A remotely controlled, unmanned, rotorcraft, such as a drone, can measure an electrical parameter. The rotorcraft includes an electrically conductive contact element having a rigid substrate perpendicular to the connecting arm. The element is coated, at least on the face thereof opposite said arm, with a coating made of conductive flexible material.

### CROSS-REFERENCE TO RELATED APPLICATIONS

See Application Data Sheet.

### STATEMENT REGARDING FEDERALLY SPONSORED RESEARCH OR DEVELOPMENT

Not applicable.

### THE NAMES OF PARTIES TO A JOINT RESEARCH AGREEMENT

Not applicable.

### INCORPORATION-BY-REFERENCE OF MATERIAL SUBMITTED ON A COMPACT DISC OR AS A TEXT FILE VIA THE OFFICE ELECTRONIC FILING SYSTEM (EFS-WEB)

Not applicable.

### STATEMENT REGARDING PRIOR DISCLOSURES BY THE INVENTOR OR A JOINT INVENTOR

Not applicable.

### BACKGROUND OF THE INVENTION

### 1. Field of the Invention

The invention relates to an unmanned aircraft of the remotely controlled rotorcraft type intended to perform measurements of electrical parameters on an object, in particular resistance measurements on buildings whose significant height makes inspections difficult. More specifically, and according to a preferred example which will be developed in greater detail in the present text, the invention is particularly applicable to the field of wind turbines, for checking their lightning path.

### 2. Description of Related Art Including Information Disclosed Under 37 CFR 1.97 and 37 CFR 1.98

In order to be compliant with the standards in force, a wind turbine must be equipped obligatorily with protection against lightning strikes. In practice, such protection takes the form of a lightning path with which all the turbines are provided, and which connects each blade to the ground by means of a conductive cable. Metal receptors are implanted in several locations along the wind turbine blade, attached at the surface and connected to the cable constituting said lightning path. This cable is most often made of copper, and connected to the earth at the bottom of the wind turbine. In most cases, failure of a lightning path results either from a manufacturing defect or from damage caused by a lightning strike. During a measurement, the consequence of the defect or damage is an increase in the electrical resistance of the lightning path.

In the wind turbine industry, lightning paths are still often inspected using a cumbersome procedure consisting of sending a rope access technician who tests the conductive receptors implanted along the blades using an ohmmeter. The principle is to measure the electrical resistance of the lightning path from one place to another, so as to verify whether it is in good condition or not. However, the work of the rope access technicians is risky, and operators must particularly be harnessed to be able to move along the surfaces of the blades of the wind turbine. The inspections take a lot of time. Moreover, they require external equipment, to lift the rope access technician, which are heavy and expensive. Briefly, such operations are costly to carry out.

In response to these problems, it has been proposed to use unmanned flying machines, of the drones type, which make it possible to substantially lighten the total bill of control operations, to perform them more quickly, and especially to make it more secure. This is, for example, the case of the solution proposed in document EP 2 985 459, which describes a quadricopter drone directed by means of a CCD camera, and provided with a rod at the end of which conductive copper wool attached to a plate located at the end of said rod makes it possible to establish a conductive connection with a contact point connected to the lightning path of a wind turbine blade. In document EP 3 211 226, an alternative solution is presented, wherein a cap or a plate, to be made of magnetic material, allows the drone to come into contact with such a conductive contact point, still in the example of a wind turbine blade.

These different solutions aiming to establish a connection with the wind turbine points to one of the difficulties of the exercise, namely that of making electrical contact that is sufficient, mechanically and temporally, to perform a quality measurement able to be exploited by a measuring instrument. Such an instrument, in order not to overburden the drone, generally remains in the hands of the person or the team in charge of performing operations for inspecting the validity of the lightning path, who remain at the bottom of the wind turbine mast. The measuring instrument is connected on the one hand to the earth at the bottom of the wind turbine, and on the other hand to a cable running from the flying machine and electrically connected to the lightning path via the electrical connection established by the intermediary of the drone with the contact point on the wind turbine.

It is the establishment of an electrically reliable contact between an unmanned aircraft and an object such as a wind turbine blade which constitutes the problem that the present invention addresses. The proposed solution in particular makes it possible to address to the dual problem of establishing both a mechanical connection that is consistently stable without affecting the durability of the structure of the flying machine, and a proper electrical connection for taking at least one measurement.

The issue of the consistently stable mechanical connection stems from the very structure of the drone, and more particularly to the connection between on the one hand the contact element at the end of an arm protruding from the perimeter of said drone, and on the other hand the frame of said drone. The issue of the electrical connection is no less significant, since it must guarantee the ability to obtain a correct signal as soon as a mechanical contact, of whatever stability, has been established. In document US 2016/0047850, the mechanical principles to which the contact element connected to the drone should adhere are mentioned (mounting with spring means), but without describing a technical configuration that precisely addresses the matter. For the electrical aspect, the text says not much more, mentioning the use of copper wool, without it being precisely known how it is implanted in the configuration, which is itself described in very general terms. One of the objectives of the invention is therefore to propose a configuration that is successful on a technical level.

### BRIEF SUMMARY OF THE INVENTION

To this end, it is proposed to use remotely controlled, unmanned, rotorcraft, such as a drone, essentially comprising:
an electrically conductive contact element, comprising at least one conductive plate;
a mechanism for connecting the contact element to the arm;
said arm and the connecting mechanism holding the contact element at a distance from the frame greater than the distance from the axis of rotation of at least one rotor of the rotorcraft to the frame in the direction of the roll axis, increased by the radius of the disc swept by the blades of said rotor;
an electrically conductive cable, a first end of which is connected to the contact element and a second end is connectable to an electrical measurement device terminal, for example of ohmic resistance measurement.

According to the invention, the electrically conductive contact element comprises a rigid substrate perpendicular to the coated connecting arm, at least on its face opposite said arm, with a covering made of flexible conductive material.

According to a first variant, the substrate comprises an outer board, the outer face of which is covered with copper wool and an inner board separated from the outer board by rods of shape parallel to the arm allowing the adjustment of the distance separating the plates, the layer of copper wool covering the outer board extending so as to produce a flexible wall joining at least two of said rods. Preferably, foam is interposed between the copper wool and on the one hand the outer board, and between the copper wool and on the other hand the rods joined by the copper wool, to make it possible to absorb any impacts at the time of contact with the blade to be measured. This also streamlines the device.

For the electrical connection, in this case, at least one wire constituting the conductive cable is attached to the exterior face of the outer board, for example by means of metal screws whose head is on the side of said exterior face.

According to one possible configuration, the outer and inner substrates are inscribed substantially in circles defined by three points indicated by the axes of three rods connecting them. Therefore, there are preferably only three rods, said circles being strictly those that circumscribe the substrates.

In fact, according to one possibility, the outer substrate takes the form of a wheel-shaped annular disc with an outer rim wherein the rods and spokes converging toward a hub for fastening the arm are attached, and the inner board comprises an interior shape joining the fastening zones of the rods, the center of which is provided with an orifice for the passage of the arm. These fastening zones are for example through-cylinders connected to the center by arms connected to one another via curved lines.

In this alternative form, to prevent the blade of the wind turbine from coming into contact with the rotors of the rotorcraft, a protection system is provided, consisting of two rigid masts of the same length fastened to the inner board, developing radially by forming an acute angle between them, and connected in the vicinity of their free ends by a rigid wire. In particular, this makes it possible to take the measurement at the end contact of the blade without any risk to the drone.

A mechanism for strengthening said protection system is also provided, which consists of a rod of shape parallel to said rigid wire, integral with the outer board and protruding, at the ends of which rigid stays are attached, which are also attached to the free ends of the masts.

According to a second variant, the electrically conductive contact element comprises at least one conductive plate constituting the rigid substrate, coated with an outer cushion layer comprising at least one flexible synthetic foam tape surrounded by a covering made of flexible conductive material.

In this second case, to address the particular problems highlighted above, the coating of the conductive plate, on an outer side in charge of contact with a receptor of the object to be inspected, therefore comprises a particular covering that fulfills a dual function: electrical due to the conductive nature of a part of the coating in contact with the plate itself conductive, and mechanical—protective of the structure which undergoes impacts at each approach—due to the use of a flexible foam, which is consequently resilient.

The specific nature of the outer layer confers on the assembly an ability for first surface absorption of mechanical stresses which arise at the moment of the first physical contacts between the drone and a receptor of the object of the measurement, contacts that in many cases involve impacts, without the electrical connection excessively disturbing a contact that can be unstable. Since it is the exterior covering of the plate that performs the first technical approach of the double mechanical and electrical function, it constitutes an important constituent of the contact element.

More specifically, each strip of the outer cushion layer may consist of a core of polyether-urethane foam covered with a fabric covering composed of polyester fibers densely woven with copper and nickel fibers. Since each strip is completely covered with this material, the material is present in an exterior face of the strip in contact with the object to be measured and in an interior face in contact with the conductive plate, and it is thus able to transmit the electrical state of said object to the operators.

According to one possibility, the conductive plate is preferably made of aluminum, the reduced weight of which is more easily transportable by a drone. In this scenario, at least one strand of the conductive cable can be attached to one face of the conductive plate facing the frame of the rotorcraft, that is to say the “inner” face of the contact element.

In certain scenarios, the receptors in contact with which the measurement is taken are sunk into the outer envelope of the object, and the measurement to be carried out is in such cases more complicated. In such a case, it is provided that at least one conductive stud resiliently deformable at least in the direction of the axis of the arm protrudes from the cushion layer along said axis of the arm, each stud being electrically connected to at least one strip of the cushion layer. According to one possibility, each stud is in practice made up of a conductive spring attached to the plate, each spring being surrounded by a flexible conductive tape that covers it at least partially, at least a portion of said proximal springs of the plate being in contact with the conductive coating of at least one strip covering the conductive plate. When the receptor is sunk in, these studs or springs that constitute just as many resilient axial protuberances exceeding the conductive padding are charged to make contact with the sunk receptors. It should be noted that in this configuration too, the electrical problem and the mechanical problem related to the first surface damping are handled together, as impacts may occur during the contacts.

In most configurations, the conductive plate is attached, via the connection mechanism, perpendicular to the connecting arm, the cushion layer then coating a face of the conductive plate of the distal contact element of the rotorcraft frame. This is in fact the face of the plate which is oriented toward the outside of the drone/arm/contact element assembly, and which faces the object to be measured.

To face yet another type of measurement, for example at the end of blades of a wind turbine, the conductive plate may however comprise two panels attached perpendicularly to each other in a L shape, a first panel of shape parallel to the axis of the arm comprising, on its inner face, the cushion layer, the second panel of shape perpendicular to the axis of the arm comprising the mechanism for connecting the conductive plate to the arm. The outer covering is the same as in the previous configurations. The configuration allows for example an approach along the axis of a blade, which may require different guidance to obtain more precise positioning, knowing that the movement of the drone is then done in another direction as previously, rather perpendicularly to the axis of the arm carrying the contact element.

According to one possible configuration, the mechanism for connecting the conductive plate to the arm may comprise on the one hand a double ball joint sliding along the axis of the arm, and on the other hand first return means for returning the plate to the position perpendicular to the axis of the arm and second return means urging the plate into a deployed distal position of the frame.

The conductive plate coated with the conductive padding of the invention then benefits from 4 degrees of freedom when mechanical stresses are exerted therein, in most cases when it comes into contact with an object to be tested. In addition, the return means improve the contact pressure and consequently the electrical contact, making it possible to carry out the measurement under the best conditions.

More specifically, according to the invention, the connection mechanism may comprise a substrate attached to the conductive plate and provided with a recess for a ball joint placed at the end of a pole able to slide in a slideway provided in the arm, said substrate comprising n fastening feet to which the first ends of n identical compression springs are attached, the second ends of which are attached to a ring attached to the pole, according to an axially symmetric configuration relative to the sliding axis in the arm.

Preferably, the feet and the compression springs are four in number (4). Axial symmetry, within the meaning of the invention, means that the springs attached to the feet together exert a resultant force, the component of which in a plane perpendicular to the axis of the arm is zero.

It should be noted that the pole may comprise, in the vicinity of the ball joint, a motorized articulation that can be actuated by remote control between a straight state of the pole and at least one angled state wherein a section of the pole comprising the ball joint is bent relative to the rest of the pole and to the arm. Such an articulation makes it possible to give an even more clear direction to the contact element which then is at an angle relative to the rest of the arm connected to the drone. The degrees of freedom associated with the existence of the ball joint always apply, with an approach mode by the contact element of the object to be measured, which is different due to the bend.

More specifically, the connecting mechanism is such that the pole can slide in a sliding tube linked to the arm of the rotorcraft, and it has at its end opposite the ball joint a carriage sliding on at least two shafts of a set of parallel shafts forming the arm, one board of said arm placed in the vicinity of its proximal end of the conductive plate serving as a stop to a first compression spring interposed between said board and the ring of the pole or the joint.

This first spring is provided to absorb the axial components of the resultant forces of the contacts and in particular to impacts, while guaranteeing that once past the transient mechanical effects associated therewith, the electrical connection can be established optimally, since the contact element is then permanently pushed back against the receptor to be tested.

Preferably, to further refine the absorption mechanism of impacts, this board is able to slide on at least two shafts of the arm, a second compression spring being interposed between said board and an intermediate stop attached to the shafts of the arm. The two springs do not have the same stiffness, so that their mechanical effects combine and act temporally in an offset manner, their distinct absorption capacity preferably being expressed at least partially sequentially. Said board may also comprise, according to the invention, the slide tube of the pole, said tube itself being able to slide into an orifice of the intermediate stop.

The axial guiding is therefore multiple, on the one hand for the pole in the tube and on the other hand for the tube in the orifice, reflecting the existence of the two springs of different stiffnesses which allow differentiated control of the movements of the pole and consequently of the contact element on the one hand, and of the plate forming a stop of the first spring on the other hand. This sliding guidance is also dependent on the carriage, the guidance of the plate, etc.

According to one possible configuration, the intermediate stop may also serve as a substrate for a mast at the upper end of which are secured optical means such as at least one camera and/or at least one guide laser beam emitter. This is means for assisting in control on-board the drone, and which are in this case fixed at the arm, that is, far forward relative to the frame. The camera(s) can operate in combination with laser pointers provided to help the pilot better target, in flight, the surface receptor that signals the existence of a connection with the lightning path of a wind turbine blade. With this visual aid, said pilot can manage the approach of the target located on the object in an optimal manner.

### BRIEF DESCRIPTION OF THE SEVERAL VIEWS OF THE DRAWINGS

The invention will now be described in more detail by means of the appended figures, which represent a non-limiting example of implementation of the invention.

FIG. 1 shows a schematic view of a comprehensive system for measuring the failure of the lightning path of a wind turbine using a drone according to the invention.

FIG. 2 shows in perspective view a part of an arm secured to a drone and comprising a contact element according to the second variant of the invention.

FIG. 3 shows in three-quarter perspective view the first variant of the contact element.

FIG. 4 shows in rear three-quarter perspective view said first variant of the contact element.

FIG. 5 shows a side elevation view of the first variant of a contact element.

FIG. 6 shows in front perspective view this first variant of a contact element.

FIG. 7 shows a perspective view of the contact element of the second variant.

FIG. 8 shows a perspective view of an alternative mode of the second variant of a contact element more particularly suitable in the case of sunken lightning path measurement receptors.

FIG. 9 shows a perspective view of a third variant of a contact element for taking largely axial measurements, for example at the end of wind turbine blades.

FIG. 10 shows another perspective view of a variant in which the mechanism for connecting the contact element to the arm can be articulated, the articulation of which keeps state of the arm straight.

FIG. 11 shows a perspective view of the same variant with the arm in the angled state.

FIG. 12 shows a perspective view of a part of the connection mechanism of the contact element to the arm, comprising more particularly the ball joint and the first return means of said plate in a position perpendicular to the axis of the arm.

FIG. 13 shows a top plan view of a portion of the connecting mechanism of the conductive plate of the second variant to the arm, more fully showing the second return means for returning the contact element, with the contact element/pole assembly in the axially deployed rest position.

FIG. 14 shows a perspective view of this mechanism, with the contact element/pole assembly in the axially contracted position, when the second return means are urged by mechanical stresses applied to the contact element.

### DETAILED DESCRIPTION OF THE INVENTION

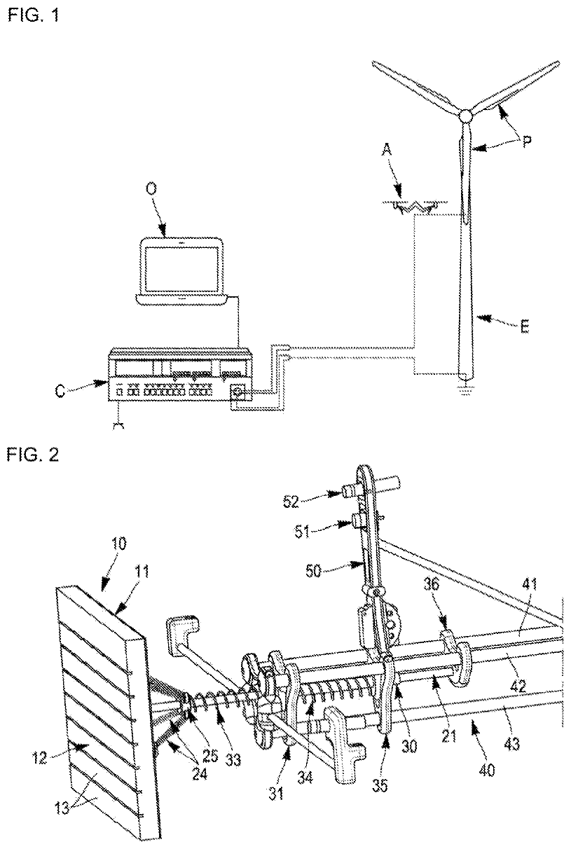

With reference to FIG. 1, the complete measurement system shown very schematically comprises a drone A directed by an operator, for example by means of a CCD camera, and provided with a pole at the end of which a contact element makes it possible to establish an electrical connection with a disc, in this case placed on a blade P of the wind turbine E. Said contact element, which will be described more substantially below, must produce an electrical contact sufficient to perform a quality measurement able to be exploited by a measuring instrument C which can be coupled to a computer O on which an application is specifically provided for processing the measured signals. The measurement and the usage of the results therefore remain in the hands of an operator in charge of carrying out operations for inspecting the validity of the lightning path, who remains at the bottom of the mast of the wind turbine E, and who may where appropriate be the one controlling the drone A. The measuring instrument is connected on the one hand to the ground at the bottom of the wind turbine E, and on the other hand to a cable which runs from the flying machine A and is electrically connected to the lightning path via the electrical connection established by means of the drone A with the contact point on the wind turbine E.

The contact element 10, as shown in particular in FIGS. 2 to 9, comprises, in its second variant, a plate 11 coated, on its face opposite the arm 40, with a cushion layer 12 consisting of a plurality of strips 13, the core of which is made of flexible synthetic foam, for example made of polyether-urethane. This core is surrounded by a fabric covering that is also flexible, for example composed of woven polyester fibers with copper and nickel fibers, metal fibers making it conductive. All these strips 13, individually and collectively, lead to electricity towards the plate 11, on which they are for example bonded by means of a conductive adhesive.

Considering their deformability, all the strips 13, the free surfaces of which are intended to be potentially in contact with the object to be measured, can come into contact with, for example, a surface receptor of a wind turbine E blade P connected to a lightning path, as in the example of FIG. 1. The effective contact zone therefore performs an electrical connection with a cable that connects the contact element 10 with the measuring instruments C, also connected to the ground to close the circuit.

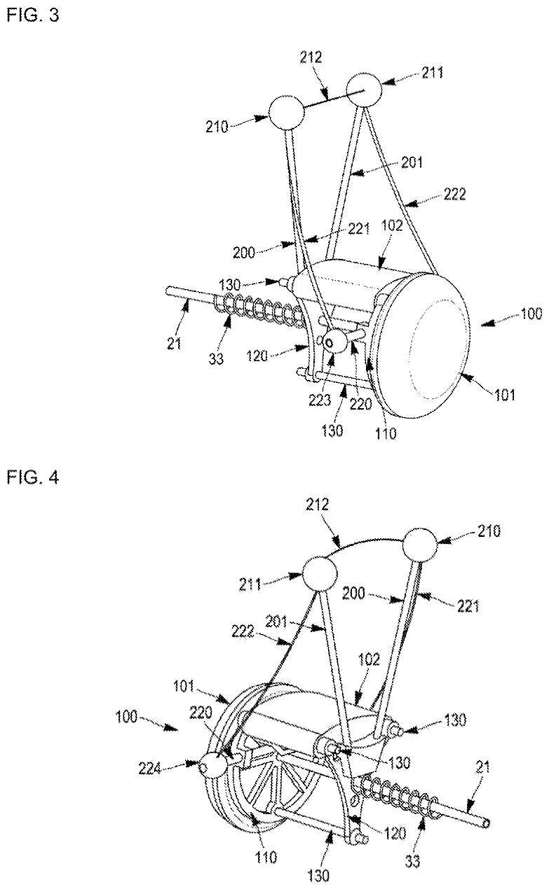

FIGS. 3 to 6 show the first variant of a contact element 100, having conductive copper wool in coatings 101, 102 in two orientations, which are electrically connected and preferably mechanically. The copper wool coating part 101 is arranged on the outer board 110, which is connected to an inner board 120 via three rods 130. Foam is interposed between the substrate and the copper wool, and also between the rods 130 involved and the copper wool which covers them. The plates 110, 120 are not made of a conductive material. The distance from the two plates 101, 102 is adjustable in the direction of these rods 130. At least one wire (not shown) constituting the aforementioned connecting cable is electrically connected to the copper wool, for example by means of a metal screw screwed into the outer face of the plate 110, said wire being attached between the head of the screw and the outer face of the plate 110. Preferably, provision has been made for the cable to consist of three screws.

As indicated, this contact element 100 has a protection system making it possible to prevent the drone rotors in particular from being damaged by the blade on which the measurement is being taken. This system has two poles 200, 201 at the ends of which there are protective balls 210, 211, connected by a rigid wire 212 which bars access to the blade if it is in motion. An additional mechanism for reinforcing the protection system is provided within the scope of the invention. It comprises a rod 220 of parallel shape to said rigid wire 212, which is rigidly attached to the outer board 110, on its inner face, and protrudes on each side. Rigid stays 221, 222, also attached to the protective balls 210, 211 of the masts 200, 201, are attached via other plugs 223, 224. The assembly forms a protective structure that preserves the integrity of the drone of the invention even in the event that the blade of the wind turbine is in motion.

The two masts 200, 201 are actually oriented upward, when the drone is in flight, and form a downward-pointing triangle with the rigid wire 212, in the vicinity of the arm 21 or the lower rod 130. There is preferably a vertical median plane of symmetry. The production of the measurements, and the attachment of the contact element 100 to the drone A, obey the same logic as with the second variant below, and are explained in more detail in the following paragraphs.

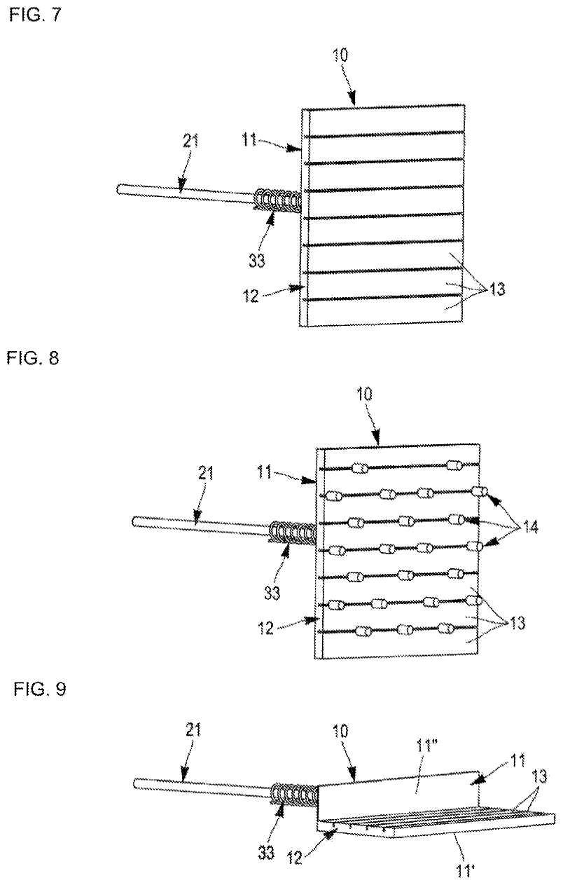

The contact element 10 of the second variant of FIG. 7 is standard, whereas it comprises additional components in the configuration of FIG. 8: conductive protuberances 14 extending parallel to the axis of the arm 40, and which are for example and preferably made in the form of resiliently deformable studs 14, at least in the axis of the arm 40, for example springs covered with a conductive tape. These conductive studs 14 have a deformability which makes the outer surface of the padding 12, when it is equipped with said studs 14, able to touch receptors sunk into a surface and to produce an appropriate electrical connection therein, making the contact element 10 effective even when the test receptors are not flush with the surface of the object to be inspected, for example a wind turbine E blade P.

The performance of the measurement is also somewhat unique for measurement points located in specific areas such as the ends of the blades P of the wind turbine E. A specific contact element 10 has been developed in response to the problems that then arise, the configuration of which appears in FIG. 9. In this case, the conductive plate 11 is L-shaped, which means that it comprises two panels 11′ and 11″ attached perpendicularly to each other, so as to allow approaches adapted to geometries such as those of blade tips P. In practice, a first panel 11′ of the plate 11 is oriented substantially parallel to the axis of the arm 40. It is this panel 11′ which has, on its interior face, that is, the face of the interior volume partially delimited by the two panels 11′ and 11″, the cushion layer 12. The second panel 11″ is consequently oriented substantially perpendicularly to the axis of the arm 40, and comprises the mechanism for connecting this part 11″ of the conductive plate 11 to the arm 40, which will be explained in more detail below.

With this contact element 10, the orientation of the conductive cushion layer 12 relative to the rest of the drone A is different from that of FIGS. 7 and 8. This is explained in particular by the fact that the approach is being made, in these particular measurement configurations, in the direction of the axis of the blade P, and that the drone A is moving in a direction that is also of a shape perpendicular to the direction of the approaches made with the contact elements 10 of FIGS. 7 and 8: in substance, the drone A is moving generally vertically for the taking of the measurements, and not substantially horizontally as in the preceding configurations.

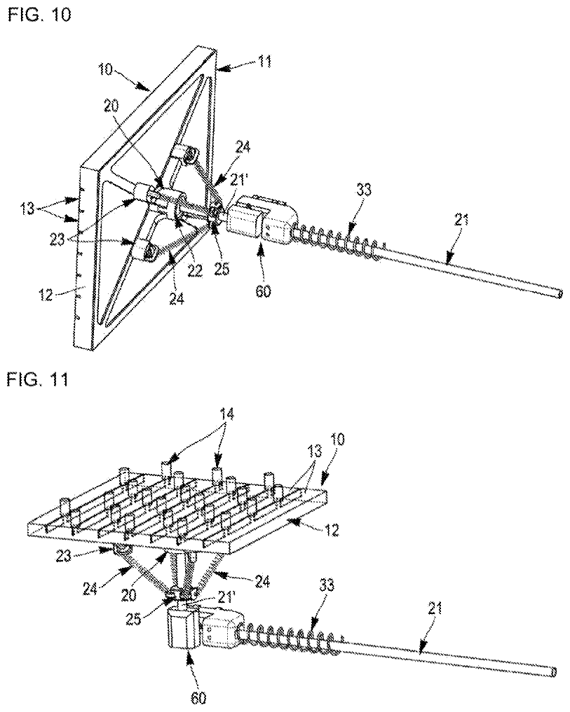

FIGS. 10 and 11 show the existence of an articulation 60 placed on the pole 21 in the vicinity of the ball 22 and the ring 25, which consequently divides the pole between a main section 21 and an end section 21′ which can be arranged bent, as shown in FIG. 11 in a configuration provided with the variant of the contact element 10 with deformable rods 14 of FIG. 4. The purely straight configuration of FIG. 10, with the variant of the contact element 10 of FIG. 7, allows for operation as devices without articulations 60. This articulation is motorized, that is to say that it can be controlled remotely, from the operator standing for example at the base of a wind turbine E, which can give him an angle depending on the configuration of the object to be inspected. This may be any angle, the adjustment being continuous in an angular interval depending on the configuration of the articulation 60. In FIGS. 10 and 11, the angular sector covered by said articulation 60 is on the order of 90°.

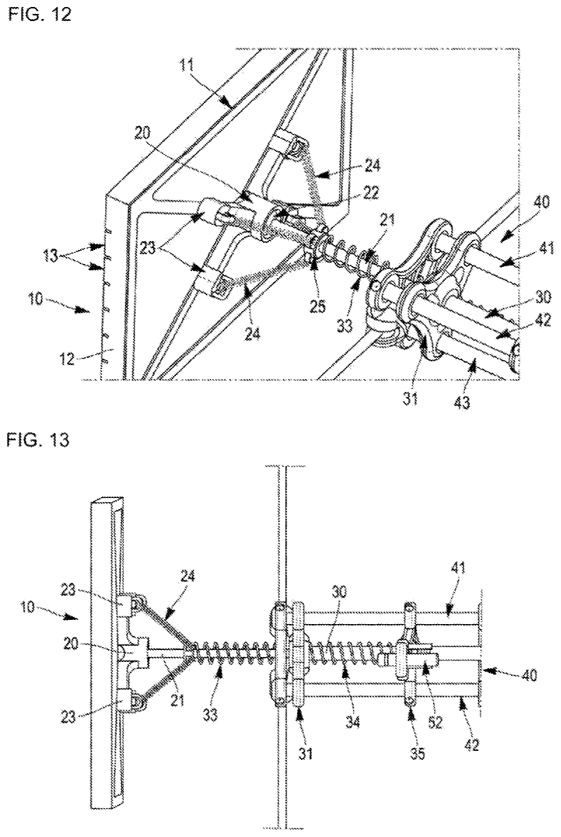

FIG. 12 shows more precisely the connection mechanism with four degrees of freedom that connects the contact element 10 to the arm 40, which may also be understood from FIGS. 2, 10 to 14. A substrate 20 is attached to the conductive aluminum plate 11, a central sleeve of which comprises a recess for a ball joint 22 constituting the end of a pole 21 arranged slidably in the arm 40. This substrate 20 also comprises four feet 23 for fastening to the plate 11, the free ends of which have identical compression spring 24 fastening means, which are also fastened to a ring 25 of the pole 21. The assembly has a symmetry with respect to the axis of the arm 40, as is necessary to guarantee the permanent return of the pole 21 to the rest position perpendicular to the plate 11.

The mechanism for sliding the pole 21 in the arm 40, visible more completely in FIGS. 2, 13 and 14, comprises a slide tube 30 rigidly connected to a board 31 movable in translation on three shafts 41, 42, 43 forming the arm 40. A first compression spring 33 is placed between the ring 25 and the board 31. A second compression spring 34, of different stiffness from the compression spring 33, is interposed between the board 31 and an intermediate stop 35, comprising an orifice wherein the tube 30 is able to slide freely.

The pole 21 is attached, at its end opposite the ball joint 22, to a carriage 36 sliding on the shafts 41, 42 of the arm 40. The operation of the sliding controlled by the compression springs 33, 34 is then the following: when a stress is exerted on the contact element 10, for example at the moment of contact with the receptor of a wind turbine E blade P, the component of this stress that parallels the axis of the arm 40 causes the movement of said contact element 10 toward the frame of the drone A, the drone A/arm 40/contact element assembly 10 then being retracted. The force applied to the contact element 10 is absorbed by the springs 33, 34, which may optionally contract sequentially, due to their different stiffness, depending on the intensity of the stress.

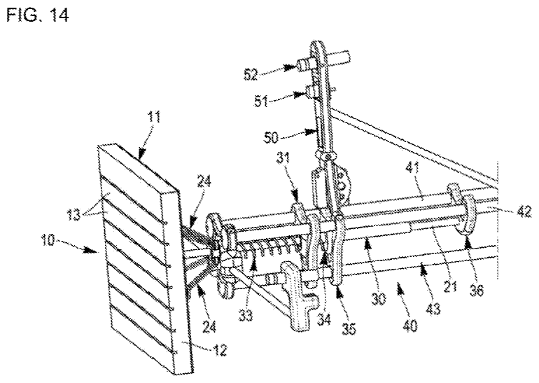

When the contact element 10 moves in the direction of the frame of the drone A (not shown), the pole 21 slides in the tube 30, which ensures a degree of guidance for said sliding, the main guide of which is however ensured by the carriage 36 which slides on the shafts 41, 42 of the arm 40. The spring 34 contracts, and the board 31 is moved: this is what is shown by FIG. 14. In this case, the tube 30 moves into an orifice of the intermediate stop 35. If necessary, in particular if the axial stress is high, the spring 33 is also stressed in compression.

Since the stresses applied on the contact element 10 are rarely only oriented along the axis of the arm, other stress components apply, which lead to the ball joint 22 rotating in its recess.

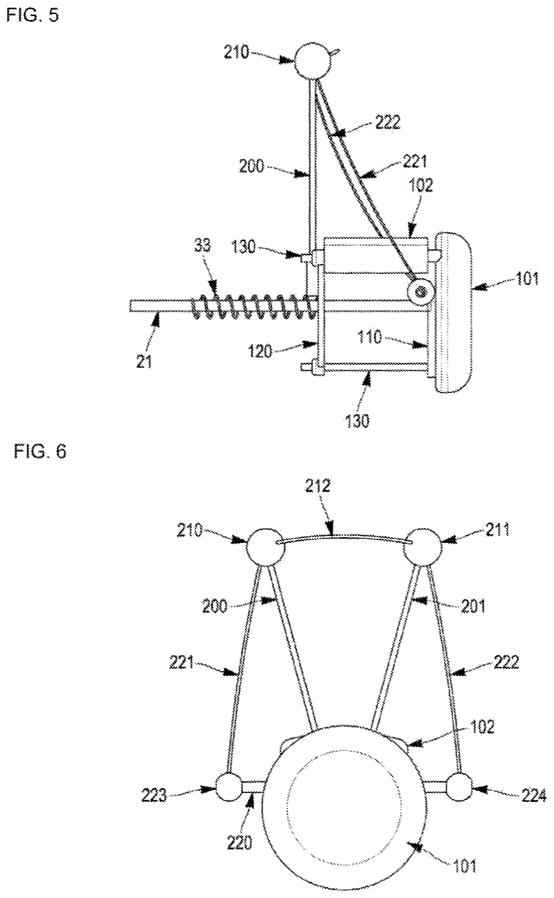

As soon as the stress ceases to apply, for example if the measurement has been made and the contact of the contact element 10 with a receptor ceases, the system must return to its rest state: for this purpose, the springs 24 return the pole 21 in a position perpendicular to the plate 11 and the springs 33, 33 regain their initial shape, returning the connection mechanism between the contact element 10 and the arm 40 to its deployed position, shown in FIGS. 2, 13 and 14. It should be noted that said mechanism, when it applies to the version of FIG. 5 of the contact element 10, does not comprise the ball-joint device 22 and springs 24. Only the part managing the sliding remains. For this variant, the connecting mechanism is attached to the panel 11″ of the plate 11.

According to the invention, piloting assistance means are installed in the drone, which are in this case fixed in the upper part of a part comprising the intermediate abutment 35 and having for this purpose a mast 50: this is in a possible configuration and as already mentioned of at least one camera 51 able to operate in combination with laser pointers 52, which are for example managed by the system to intersect in front of the contact element 10 in order to assist the pilot in better targeting, in flight, a surface receptor, so as to allow a connection with the lightning path of a wind turbine blade.

Many solutions are possible in this respect, and more precisely, the piloting assistance means could be replaced by the implementation of lidar guidance. The signals and images that they provide to the pilot located at the bottom of the wind turbine allow substantial assistance for the piloting of the drone, the pilot being able to optimally manage the approach of the target located on the object, after having chosen, depending on the nature of said target, one of the three contact elements described previously.

The example technologies given above are not exhaustive of the invention, which instead encompasses multiple variants of shapes and structures, such as for example for the connection mechanism between the contact element 10, 100 and the arm 40, or the design modes of the conductive cushion covering of the contact element 10, 100 as has been shown by way of illustration in the configurations described in greater detail above.

We claim:

1. A remotely controlled, unmanned, rotorcraft for measuring an electrical parameter, comprising:
an electrically conductive contact element;
a mechanism for connecting the contact element to an arm for connecting the contact element to the frame of the rotorcraft.
wherein said arm and the connection mechanism hold the contact element at a distance from the frame greater than the distance from the axis of rotation of at least one rotor of the rotorcraft to the frame in the direction of the roll axis, increased by the radius of the disc swept by the blades of said rotor; and
an electrically conductive cable, a first end of which is connected to the contact element and a second end is connectable to an electrical measurement device terminal of ohmic resistance, at least 4 bladed rotors,
wherein the electrically conductive contact element comprises a rigid substrate perpendicular to the coated connecting arm, at least on its face opposite said arm, with a covering made of flexible conductive material.

2. The remotely controlled, unmanned, rotorcraft according to claim 1, wherein the substrate comprises an outer board, the outer face of which is covered with copper wool and an inner board separated from the outer board by rods of shape parallel to the arm allowing the adjustment of the distance separating the plates, the layer of copper wool covering the outer board extending so as to produce a flexible wall joining at least two of said rods.

3. The remotely controlled, unmanned, rotorcraft, according to claim 2, wherein the foam is interposed between the copper wool and the outer board, and between the copper wool and the rods joined by the copper wool.

4. The remotely controlled, unmanned, rotorcraft, according to claim 3, wherein at least one wire constituting the conductive cable is attached to the exterior face of the outer board.

5. The remotely controlled, unmanned, rotorcraft, according to claim 3, wherein the outer and inner substrates are inscribed substantially in circles defined by three points indicated by the axes of three rods connecting them, and
wherein the outer substrate is comprised of a wheel-shaped annular disc with an outer rim wherein the rods and spokes converging toward a hub for fastening the arm are attached, and wherein the inner board comprises an interior shape joining the fastening zones of the rods, the center of which is provided with an orifice for the passage of the arm.

6. (canceled).

7. The remotely controlled, unmanned, rotorcraft, according to claim 2, further comprising: a protection system being comprised of two rigid masts of the same length fastened to the inner board, developing radially by forming an acute angle between them, and connected in the vicinity of their free ends by a rigid wire.

8. The remotely controlled, unmanned, rotorcraft, according to claim 7, wherein a mechanism for strengthening the protection system is comprised of a rod of shape parallel to said rigid wire, integral with the outer board and protruding, at the ends of which rigid stays are attached, which are also attached to the free ends of the masts.

9. The remotely controlled, unmanned, rotorcraft, according to claim 8, wherein the electrically conductive contact element comprises at least one conductive plate comprising the rigid substrate, coated with an outer cushion layer comprising at least one strip being comprised of flexible synthetic foam surrounded by a covering made of flexible conductive material, and
wherein each strip is comprised of a core of polyether-urethane foam covered with a fabric covering composed of polyester fibers densely woven with copper and nickel fibers.

10. (canceled)

11. The remotely controlled, unmanned, rotorcraft, according to in claim 9, wherein the conductive plate is comprised of aluminum, at least one strand of the conductive cable being attached to one face of the conductive plate facing the frame of the rotorcraft.

12. The remotely controlled, unmanned, rotorcraft, according to claim 9, wherein at least one conductive stud resiliently deformable at least in the direction of the axis of the arm protrudes from the cushion layer along said axis of the arm, each stud being electrically connected to at least one strip of the cushion layer.

13. The remotely controlled, unmanned, rotorcraft, according to claim 12, wherein the stud is comprised of a conductive spring attached to the plate, each spring being surrounded by a flexible conductive tape which covers it at least partially, at least a portion of said proximal springs of the plate being in contact with the conductive coating of at least one strip covering the conductive plate.

14. The remotely controlled, unmanned, rotorcraft, according to claim 9, wherein the conductive plate is attached, via the connection mechanism, perpendicular to the connecting arm, the cushion layer coating a face of the conductive plate of the distal contact element of the frame of the rotorcraft.

15. The remotely controlled, unmanned, rotorcraft, according to claim 9, wherein the conductive plate comprises two panels attached perpendicularly to each other in an L-shape, a first panel of shape parallel to the axis of the arm comprising, on its inner face, the cushion layer, the second panel of shape perpendicular to the axis of the arm comprising the mechanism for connecting the conductive plate to the arm.

16. The remotely controlled, unmanned, rotorcraft, according to claim 9, wherein the mechanism for connecting the conductive plate to the arm comprises a double ball joint sliding along the axis of the arm, and wherein first return means for returning the plate to the position perpendicular to the axis of the arm and second return means urging the plate into a distal deployed position of the frame.

17. The remotely controlled, unmanned, rotorcraft, according to claim 16, wherein the connection mechanism comprises a substrate attached to the conductive plate and provided with a recess for a ball joint placed at the end of a pole able to slide in a slideway provided in the arm, said substrate comprising n fastening feet to which the first ends of n identical compression springs are attached, the second ends of which are attached to a ring attached to the pole, according to an axially symmetric configuration relative to the sliding axis in the arm.

18. The remotely controlled, unmanned, rotorcraft, according to claim 17, wherein the pole comprises, in the vicinity of the ball joint, a motorized articulation that can be actuated by remote control between a straight state of the pole and at least one angled state wherein a section of the pole comprising the ball joint is bent relative to the rest of the pole and the arm.

19. The remotely controlled, unmanned, rotorcraft, according to claim 17, wherein the pole slides in a sliding tube linked to the arm of the rotorcraft and has at its end opposite the ball joint a carriage sliding on at least two shafts of a set of parallel shafts forming the arm, one board of said arm placed in the vicinity of its proximal end of the conductive plate serving as a stop to a first compression spring interposed between said board and the ring of the pole or the joint.

20. The remotely controlled, unmanned, rotorcraft, according to claim 19, wherein said board is able to slide on at least two shafts of the arm, a second compression spring being interposed between said board and an intermediate stop fixed to the shafts of the arm.

21. The remotely controlled, unmanned, rotorcraft, according to claim 20, wherein said board comprises a tube for sliding the pole, said tube being able to slide in an orifice of the intermediate stop.

22. The remotely controlled, unmanned, rotorcraft, according to in claim 20, wherein the intermediate stop serves as a substrate for a mast at the upper end of which are secured optical means such as at least one camera and/or at least one guide laser beam emitter.
